(19) United States
(12) Patent Application Publication
(10) Pub. No.: US 2017/0352839 A1
(43) Pub. Date: Dec. 7, 2017

(54) LIGHT EXTRACTING SUBSTRATE FOR ORGANIC LIGHT EMITTING DEVICE, METHOD OF MANUFACTURING SAME, AND ORGANIC LIGHT EMITTING DEVICE INCLUDING SAME

(71) Applicant: Corning Precision Materials Co., Ltd., Churngcheongnam-do (KR)

(72) Inventor: Dong Hyun Kim, Chungcheongnam-do (KR)

(73) Assignee: Corning Precision Materials Co., Ltd., Chungcheongnam-do (KR)

(21) Appl. No.: 15/538,517

(22) PCT Filed: Dec. 16, 2015
(86) PCT No.: PCT/KR2015/013795

§ 371 Date: Jun. 21, 2017

(30) Foreign Application Priority Data
Dec. 22, 2014 (KR) 10-2014-0185670

(51) Int. Cl. H01L 51/52; H01L 51/00; H01L 51/56

(52) U.S. Cl. CPC H01L 51/5268; H01L 51/56; H01L 51/0097; H01L 2251/5369; H01L 2251/303

(57) ABSTRACT

The present invention relates to a light extracting substrate for an organic light emitting device, a method of manufacturing same, and an organic light emitting device including same and, more particularly, to: a light extracting substrate for an organic light emitting device, the light extracting substrate being capable of not only maximizing the light extraction efficiency of an organic light emitting device through an undulating structure formed on a surface contacting the organic light emitting device and through a scattering structure having a maximized refractive index difference, but also of being manufactured through a simple process constituted of anode oxidation and wet coating; a method of manufacturing same; and an organic light emitting device including same. To this end, the present invention provides a light extracting substrate for an organic light emitting device, a method of manufacturing same, and an organic light emitting device including same, the light extracting substrate characterized by comprising: a base substrate; a plurality of nanotubes formed on the base substrate; and a coating layer formed on the plurality of nanotubes, sealing the top of the plurality of nanotubes, forming an air layer inside each of the plurality of nanotubes, and having undulations formed on the surface thereof due to capillary action induced by the plurality of nanotubes during forming.

### TECHNICAL FIELD

The present disclosure relates to a light extraction substrate for an organic light-emitting diode (OLED) device (or an organic light-emitting device), a method of manufacturing the same, and an OLED device including the same. More particularly, the present disclosure relates to a light extraction substrate for an OLED device, wherein the light extraction substrate can maximize the light extraction efficiency of an OLED device through a corrugated structure formed on a surface of the light extraction substrate that abuts an OLED of the OLED device and a scattering structure having a maximized refractive index difference and can be manufactured using a simple process consisting of anodic oxidation and wet coating, a method of manufacturing the same, and an OLED device including the same.

### BACKGROUND ART

In general, light-emitting devices may be divided into organic light-emitting diode (OLED) devices having a light-emitting layer formed from an organic material and inorganic light-emitting devices having a light-emitting layer formed from an inorganic material. In OLED devices, OLEDs are self-emitting light sources based on the radiative decay of excitons generated in an organic light-emitting layer by the recombination of electrons injected through an electron injection electrode (cathode) and holes injected through a hole injection electrode (anode). OLEDs have a range of merits, such as low-voltage driving, self-emission, a wide viewing angle, high resolution, natural color reproducibility, and rapid response times.

Recently, research has been actively undertaken into applying OLEDs to portable information devices, cameras, clocks, watches, office equipment, information display devices for vehicles or similar, televisions (TVs), display devices, lighting systems, and the like.

To improve the luminous efficiency of such above-described OLED devices, it is necessary to improve the luminous efficiency of a material of which a light-emitting layer is formed or light extraction efficiency, i.e. the efficiency with which light generated by the light-emitting layer is extracted.

The light extraction efficiency of an OLED device depends on the refractive indices of OLED layers. In a typical OLED device, when a beam of light generated by the light-emitting layer is emitted at an angle greater than a critical angle, the beam of light may be totally reflected at the interface between a higher-refractivity layer, such as a transparent electrode layer functioning as an anode, and a lower-refractivity layer, such as a glass substrate. This may consequently lower light extraction efficiency, thereby lowering the overall luminous efficiency of the OLED device, which is problematic.

Described in more detail, only about 20% of light generated by an OLED is emitted from the OLED device and about 80% of the light generated is lost due to a waveguide effect originating from different refractive indices of a glass substrate, an anode, and an organic light-emitting layer comprised of a hole injection layer, a hole transport layer, an emissive layer, an electron transport layer, and an electron injection layer, as well as by the total internal reflection originating from the difference in refractive indices between the glass substrate and ambient air. Here, the refractive index of the internal organic light-emitting layer ranges from 1.7 to 1.8, whereas the refractive index of indium tin oxide (ITO), generally used in anodes, is about 1.9. Since the two layers have a significantly low thickness, ranging from 200 nm to 400 nm, and the refractive index of the glass used for the glass substrate is about 1.5, a planar waveguide is thereby formed inside the OLED device. It is calculated that the ratio of the light lost in the internal waveguide mode due to the above-described reason is about 45%. In addition, since the refractive index of the glass substrate is about 1.5 and the refractive index of ambient air is 1.0, when light exits the interior of the glass substrate, a beam of the light, having an angle of incidence greater than a critical angle, may be totally reflected and trapped inside the glass substrate. The ratio of trapped light is about 35%. Therefore, only about 20% of generated light may be emitted from the OLED device.

To overcome these problems, a technology for forwardly extracting light that would otherwise be lost in the interior or at the boundaries of an OLED is required. This technology is referred to as light extraction technology. A problem solving scheme, based on light extraction technology, is to remove any factor preventing light from traveling forwards, so that that the light is not lost in the interior or at the boundaries of the OLED, or to obstruct the passage of light. In this regard, external light extraction methods and internal light extraction methods are typically used. External light extraction methods are devised to reduce total internal reflection at the boundary between a substrate and surrounding air by forming textures in the surface of the outermost portion of the substrate or coating the outermost portion with a layer having a refractive index different from that of the substrate. Internal light extraction methods are devised to reduce the waveguide effect in which light travels along the boundary between layers having different refractive indices and thicknesses instead of traveling forwards through the boundary, by forming surface textures between a substrate and a transparent electrode or forming a coating layer, having a refractive index different from that of the substrate, between the substrate and the transparent electrode.

However, conventional light extraction technology or light extraction layer forming methods have problems in that complicated processing, such as photolithography, and expensive equipment must be used. Even in the case in which surface textures are formed between the substrate and the transparent electrode, for example, an additional planarization layer must be formed between the surface textures and the transparent electrode to provide flatness. This may consequently complicate the manufacturing process while increasing manufacturing costs and manufacturing times, which are problematic.

### RELATED ART DOCUMENT

United States Patent Application Publication No. 2012-0049151 (Mar. 1, 2012)

### DISCLOSURE

### Technical Problem

Accordingly, the present disclosure has been made in consideration of the above-described problems occurring in the related art, and the present disclosure proposes an organic light-emitting diode (OLED) device (or an organic light-emitting device), wherein the light extraction substrate can maximize the light extraction efficiency of an OLED device using a corrugated structure formed on a surface of the light extraction substrate that abuts an OLED of the OLED device and a scattering structure having a maximized refractive index difference and can be manufactured using a simple process consisting of anodic oxidation and wet coating, a method of manufacturing the same, and an OLED device including the same.

### Technical Solution

According to an aspect of the present disclosure, a light extraction substrate for an OLED device may include: a base substrate; a number of nanotubes disposed on the base substrate; and a coating film disposed on the number of nanotubes to close top ends of the number of nanotubes to form a number of air gaps in the number of nanotubes, respectively, the coating film having corrugations formed on a surface thereof due to a capillary effect inducted by the number of nanotubes.

Surface portions of the coating film located above the number of air gaps may form downwardly convex surface portions.

An aspect ratio of the number of air gaps may be smaller than 1.

The coating film may be formed from a material having a refractive index different from a refractive index of a material from which the number of nanotubes are formed.

The number of nanotubes may be formed from a metal oxide.

The number of nanotubes may be formed from a titanium oxide.

The light extraction substrate may further include filler disposed in at least portions of the number of air gaps, the filler being formed from a material having a refractive index different from a refractive index of a material from which the number of nanotubes are formed.

The light extraction substrate may further include one or more scattering particles dispersed in the filler.

The scattering particles may respectively include a core and a shell surrounding the core. The core may be a hollow portion.

According to another aspect of the present disclosure, an OLED device may include the above-described light extraction substrate in a portion through which generated light exits.

According to another aspect of the present disclosure, a method of manufacturing a light extraction substrate for an OLED device may include: growing a number of nanotubes on a surface of a metal base material by performing anodic oxidation on a surface of the metal base material; and forming a coating film by coating the number of nanotubes with a liquid composite by wet coating. Corrugations are formed on a surface of the coating film by a capillary effect induced by the number of nanotubes in the wet coating.

The viscosity of the liquid composite may be controlled in a range from 1 cP to 1000 cP in the wet coating.

The metal base material used in the anodic oxidation may be formed from titanium or a titanium alloy.

Top ends of the number of nanotubes may be closed by the coating film, thereby forming a number of air gaps within the number of nanotubes, respectively, in a longitudinal direction of the number of nanotubes.

The method may further include disposing filler within the number of nanotubes before the wet coating, the filler being formed from a material having a refractive index different from a refractive index of the number of nanotubes.

Scattering particles may be dispersed in the filler in the process of disposing the filler.

### Advantageous Effects

According to the present disclosure, it is possible to maximize the light extraction efficiency of an OLED device using a corrugated structure formed on a surface of the light extraction substrate that abuts an OLED of the OLED device a scattering structure having a maximized refractive index difference.

In addition, according to the present disclosure, a light extraction substrate is manufactured using a simple process consisting of anodic oxidation and wet coating. It is thereby possible to improve processing efficiency and significantly reduce manufacturing costs and manufacturing times due to simplified processing, as compared to conventional patterning or photolithography, thereby improving productivity in the manufacturing of light extraction substrates compared to conventional cases.

### DESCRIPTION OF DRAWINGS

FIG. 1 is a cross-sectional view schematically illustrating a light extraction substrate for an OLED device according to an exemplary embodiment;

FIG. 2 is a cross-sectional view schematically illustrating a light extraction substrate for an OLED device according to another exemplary embodiment;

FIG. 3 is a cross-sectional view schematically illustrating a light extraction substrate for an OLED device according to further another exemplary embodiment;

FIGS. 4 to 6 are schematic views sequentially illustrating steps of a method of manufacturing a light extraction substrate for an OLED according to an exemplary embodiment; and

FIGS. 7 and 8 are electron microscopy images illustrating nanotubes grown by the method manufacturing a light extraction substrate for an OLED according to the exemplary embodiment.

### MODE FOR INVENTION

Hereinafter, a light extraction substrate for an organic light-emitting diode (OLED) device (or an organic light-emitting device), a method of manufacturing the same, and an OLED device including the same according to exemplary embodiments will be described in detail with reference to the accompanying drawings.

In the following disclosure, detailed descriptions of known functions and components incorporated herein will be omitted in the case in which the subject matter of the present disclosure may be rendered unclear by the inclusion thereof.

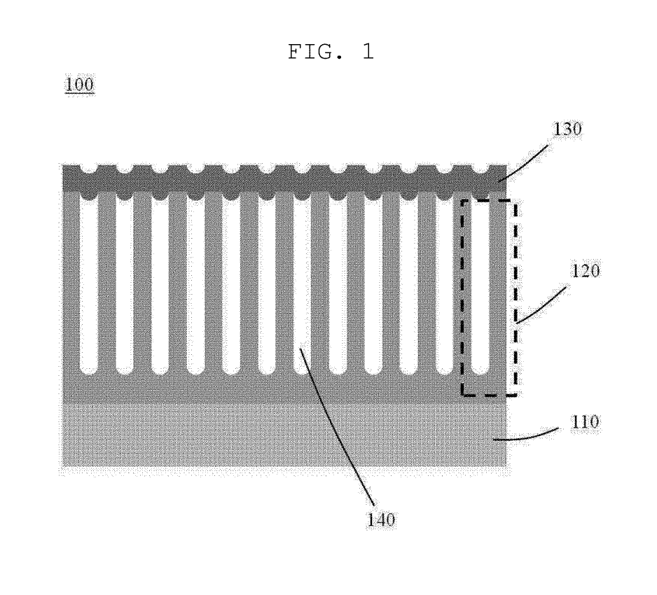

As illustrated in FIG. 1, a light extraction substrate 100 for an OLED device according to an exemplary embodiment is disposed in a portion, through which light generated by an OLED exits, to function as a path through which light generated by the OLED exits, improve the light extraction efficiency of an OLED device, and protect the OLED from the external environment.

Although not specifically illustrated, the OLED has a multilayer structure comprised of an anode, an organic light-emitting layer, and a cathode, sandwiched between the light extraction substrate 100 for an OLED device according to the exemplary embodiment and another substrate facing the light extraction substrate 100. The anode may be formed from a metal or metal oxide having a greater work function, such as Au, In, Sn, or indium tin oxide (ITO), to facilitate hole injection. The cathode may be a metal thin film form from Al, Al:Li, or Mg:Ag that has a smaller work function to facilitate electron injection. When the OLED has a top emission structure, the cathode may have a multilayer structure comprised of a semitransparent electrode of a thin metal film formed from, for example, Al, Al:Li, or Mg:Ag, and a transparent electrode of an oxide thin film formed from, for example, ITO, to facilitate the transmission of light generated by the organic light-emitting layer. The organic light-emitting layer may include a hole injection layer, a hole transport layer, an emissive layer, an electron transport layer, and an electron injection layer that are sequentially stacked on the anode. When the OLED is a white OLED used for lighting, the light-emitting layer may have, for example, a multilayer structure comprised of a high-molecular light-emitting layer that emits blue light and a low-molecular light-emitting layer that emits orange-red light. In addition, a variety of other structures that emit white light may be used. The OLED may also have a tandem structure. In this case, a plurality of organic light-emitting layers alternating with interconnecting layers (not shown) may be provided.

According to this structure, when a forward voltage is induced between the anode and the cathode, electrons migrate from the cathode to the emissive layer through the electron injection layer and the electron transport layer, while holes migrate from the anode to the emission layer through the hole injection layer and the hole transport layer. The electrons and the holes that have migrated into the emission layer recombine with each other, thereby generating excitons. When these excitons transit from an excited state to a ground state, light is generated. The brightness of the generated light is proportional to the amount of current flowing between the anode and the cathode.

The light extraction substrate 100 according to the exemplary embodiment, used to improve the light extraction efficiency of the OLED as described above, includes a base substrate 110, a number of nanotubes 120, and a coating film 130.

The base substrate 110 is a substrate supporting the number of nanotubes 120 and the coating film 130 disposed on one surface thereof. In addition, the base substrate 110 is disposed on a front portion of the OLED, i.e. an outermost portion through which light generated by the OLED exits, to allow the light to exit while functioning as an encapsulation substrate to protect the OLED from the external environment.

The base substrate 110 may be a transparent substrate formed from any transparent material having superior light transmittance and excellent mechanical properties. For example, the base substrate 110 may be formed from a polymeric material, such as a thermally or ultraviolet (UV) curable organic film. Alternatively, the base substrate 110 may be formed from chemically strengthened glass, such as soda-lime glass (SiO2-CaO-Na2O) or aluminosilicate glass (SiO₂-Al2O3-Na2O). When the OLED device 10 including the light extraction substrate 100 according to the exemplary embodiment is used for lighting, the base substrate 110 may be formed from soda-lime glass. The base substrate 110 may also be a metal oxide substrate or a metal nitride substrate. Alternatively, the base substrate 110 according to the exemplary embodiment may be a flexible substrate, more particularly, a thin glass sheet having a thickness of 1.5 mm or less. The thin glass sheet may be manufactured using a fusion process or a floating process.

The number of nanotubes 120 are formed on the base substrate 110. The number of nanotubes 120 are arranged linearly in the horizontal direction (with respect to the paper surface). The number of nanotubes 120 may be formed by anodic oxidation, which will be described in more detail later.

The number of nanotubes 120 according to the exemplary embodiment may be formed from a metal oxide that can be processed by anodic oxidation. For example, the number of nanotubes 120 may be formed from a titanium oxide.

The interior of each of the nanotubes 120 is formed as a hollow space with the top end thereof (with respect to the paper surface) being open. The top ends of the hollow spaces are closed by the coating film 130, thereby forming a number of air gaps 140. The air gaps 140 extend in the longitudinal direction of the nanotubes 120 having the shape of an erect, elongated rod or pillar, such that the aspect ratio of the air gaps 140 is smaller than 1. The air gaps 140 have a refractive index different from that of the nanotubes 120 formed from a metal oxide while complicating or diversifying paths for light generated by the OLED, thereby improving light extraction efficiency in the forward direction, i.e. light extraction efficiency toward the base substrate 110. In addition, the hollow spaces of the nanotubes 120 induce a capillary effect when the nanotubes 120 are coated with a viscous coating film 140, so that a corrugated structure for minimizing the loss of light emitted by the OLED can be formed on the surface of the coating film 130.

The coating film 130 is formed on the number of nanotubes 120 to cover the number of nanotubes 120. The coating film 130 closes the top ends of the number of nanotubes 120, more particularly, the open top ends of the inner spaces of the number of nanotubes 120, thereby forming the number of air gaps 140 within the number of nanotubes 120, respectively. The coating film 130 forms an internal light extraction layer (ILEL) of the OLED together with the number of air gaps 140 and the number of nanotubes 120 functioning as a matrix layer of the air gaps 140.

The coating film 130 according to the exemplary embodiment is formed by coating the number of nanotubes 120 with a viscous liquid composite. During the coating process using the viscous liquid composite, corrugations are formed on the surface of the coating film by the capillary effect induced by the inner spaces of the number of nanotubes 120. Specifically, the portions of the coating film 130, located above the air gaps 140, are drawn toward the air gaps 140 by the capillary effect, such that the top surfaces thereof are concave downwardly and the bottom surfaces thereof are convex downwardly. In contrast, the portions of the coating film 130, located above the edges of the nanotubes 120, are free from the capillary effect. Consequently, the surface of the coating film 130 formed on the number of nanotubes 120 has a corrugated structure. When the corrugations are formed on the surface of the coating film 130 abutting the OLED as described above, it is possible to reduce the waveguide effect by which light emitted by the OLED is lost, thereby further improving the light extraction efficiency of the OLED device.

The coating film 130 according to the exemplary embodiment may be formed from a material having a refractive index different from that of the material of the nanotubes 120 to maximize the light extraction effect of the OLED device. For example, when the nanotubes 120 are formed from a titanium oxide, the coating film 130 may be formed from a metal oxide, such as a silicon oxide, or a low refractive index polymer, the refractive index of which is lower than the refractive index of the titanium oxide. As described above, when the coating film 130, the number of nanotubes 120, and the number of air gaps 140 having different refractive indices form the internal light extraction layer having a low/high/low-refractive-index structure on the path through which light generated by the OLED exits, the light extraction efficiency of the OLED device can be improved based on the different refractive indices.

That is, when the light extraction substrate 100 according to the exemplary embodiment is provided on one surface of the OLED, through which light generated by the OLED exits, the light extraction substrate 100 can maximize the light extraction efficiency of the OLED device using the multi-refractive-index structure obtained by the coating film 130, the number of nanotubes 120, and the number of air gaps 140, the scattering structure obtained by the number of nanotubes 120 and the number of air gaps 140, and the corrugated structure formed on the surface of the coating film 130 due to the capillary effect induced by the number of nanotubes 120.

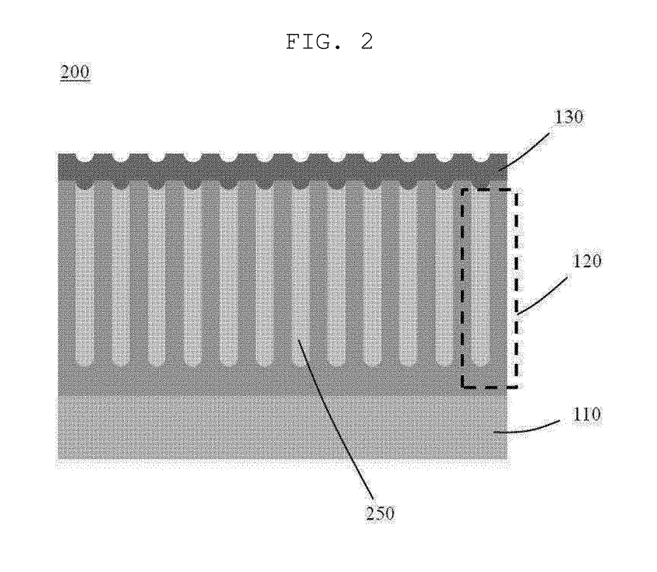

Hereinafter, a light extraction substrate according to another exemplary embodiment will be described with reference to FIG. 2.

FIG. 2 is a cross-sectional view schematically illustrating a light extraction substrate for an OLED device according to another exemplary embodiment.

As illustrated in FIG. 2, the light extraction substrate 200 for an OLED device according to another exemplary embodiment includes a base substrate 110, a number of nanotubes 120, a coating film 130, and filler 250.

Another exemplary embodiment is substantially the same as the former exemplary embodiment, except for the filler added to fill the air gaps. The same components will be denoted by the same reference numerals and detailed descriptions thereof will be omitted hereinafter.

According to another exemplary embodiment, filler 250 is disposed in the inner hollow spaces of the nanotubes 120, i.e. the air gaps 140 in FIG. 1, the top ends of which are closed by the coating film 130. The filler 250 may be provided to fill the entire portions of the air gaps 140, as illustrated in the drawing, or fill portions of the air gaps 140.

The filler 250 may be formed from a material, the refractive index of which differs from the refractive index of the material of the nanotubes 120, for example, by being lower thereto. The filler 250 functions to improve the extraction efficiency of light emitted by the OLED, based on the refractive index difference and light scattering. Here, the material of the filler 250 may also have a refractive index different from that of the material of the coating film 130 to improve the light extraction efficiency of the OLED device.

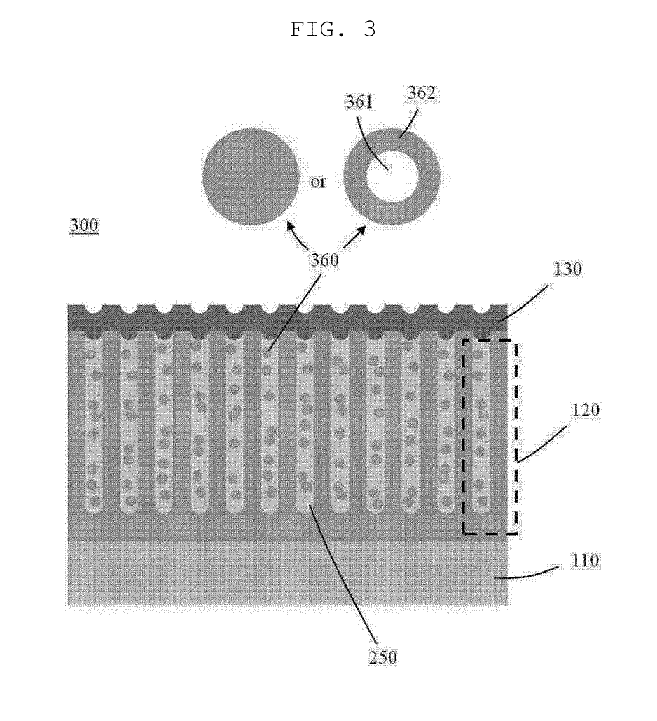

Hereinafter, a light extraction substrate according to further another exemplary embodiment will be described with reference to FIG. 3.

FIG. 3 is a cross-sectional view schematically illustrating a light extraction substrate for an OLED device according to further another exemplary embodiment.

As illustrated in FIG. 3, the light extraction substrate 300 for an OLED device according to further another exemplary embodiment includes a base substrate 110, a number of nanotubes 120, a coating film 130, filler 250, and a number of scattering particles 360.

Further another exemplary embodiment is substantially the same as another exemplary embodiment, except for the scattering particles dispersed in the filler. The same components will be denoted by the same reference numerals and detailed descriptions thereof will be omitted.

According to further another exemplary embodiment, one or more scattering particles 360 are provided. The scattering particles 360 are dispersed in the filler 250 to scatter light emitted by the OLED along a variety of paths, thereby improving the light extraction efficiency of the OLED device.

The scattering particles 360 according to further another exemplary embodiment may respectively be comprised of a core 361 and a shell 362 surrounding the core 361, the shell 362 being formed from a material having a refractive index different from that of the core 361. The core 361 may be a hollow portion. When the scattering particles 360 have a core-shell structure, the difference in refractive indices between the core 361 and the shell 362 can contribute to further improvement of the extraction efficiency of light generated by the OLED. However, the scattering particles 360 may have a single-refractive-index structure, i.e. a structure in which the core 361 is not provided inside each scattering particle. Thus, further another exemplary embodiment does not specifically limit the structure of the scattering particles 360 to the core-shell structure.

The number of scattering particles 360 dispersed in the filler 20 may be particles, all of which have a core-shell structure, or particles, all of which have a single refractive index. In addition, the number of scattering particles 360 may be a mixture of multi-refractive-index particles having a core-shell structure and single-refractive-index particles.

In addition, according to further another exemplary embodiment, the scattering particles 360 respectively have the shape of a nanoscale sphere. Alternatively, the number of scattering particles 360 may have the shape of a rod. The number of scattering particles 360 may have the same or a variety of different shapes or sizes. That is, the number of scattering particles 360 may have random sizes, distances, or shapes. When the number of scattering particles 360 are formed randomly, light extraction can be uniformly induced across a wide range of wavelength bands instead of being induced in a specific wavelength band. This feature may be more available when the light extraction substrate 300 according to further exemplary embodiment is applied to the OLED device used for lighting.

In addition, a number of voids may be dispersed within the filler 250, taking the places of the number of scattering particles 360, to take the role of the number of scattering particles 360.

Hereinafter, a method of manufacturing a light extraction substrate for an OLED according to an exemplary embodiment will be described with reference to FIGS. 4 to 6.

FIGS. 4 to 6 are schematic views sequentially illustrating steps of a method of manufacturing a light extraction substrate for an OLED according to an exemplary embodiment.

The method of manufacturing a light extraction substrate for an OLED according to the exemplary embodiment includes an anodic oxidation step and a wet coating step.

First, as illustrated in FIG. 4, the anodic oxidation step is a step of growing a number of nanotubes 120 on a metal base material by performing anodic oxidation on the surface of the metal base material. Specifically, in the anodic oxidation step, anodic oxidation is performed on the surface of the metal base material by applying a voltage to an anode and a cathode, the metal base material formed from titanium (Ti) or a titanium alloy functioning as the anode, and the cathode being formed from platinum (Pt) or graphite, such that the number of nanotubes 120 are grown on the metal base material.

After the number of nanotubes 120 are grown, before the wet coating step is performed, the interiors of the nanotubes 120 may be filled with filler (250 in FIG. 2) formed from a different material from the nanotubes 120. In this case, a number of scattering particles (360 in FIG. 3) may be dispersed in the filler (250 in FIG. 3).

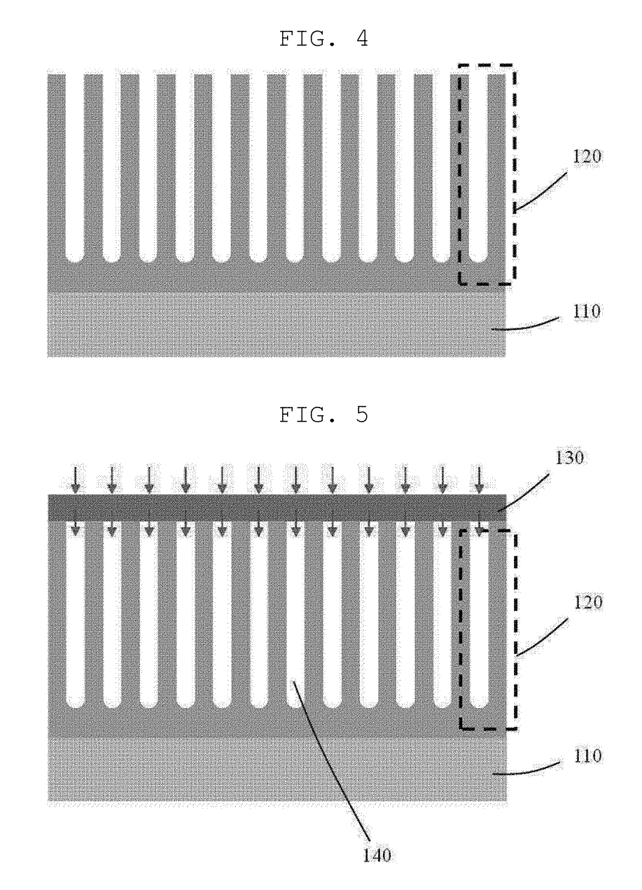

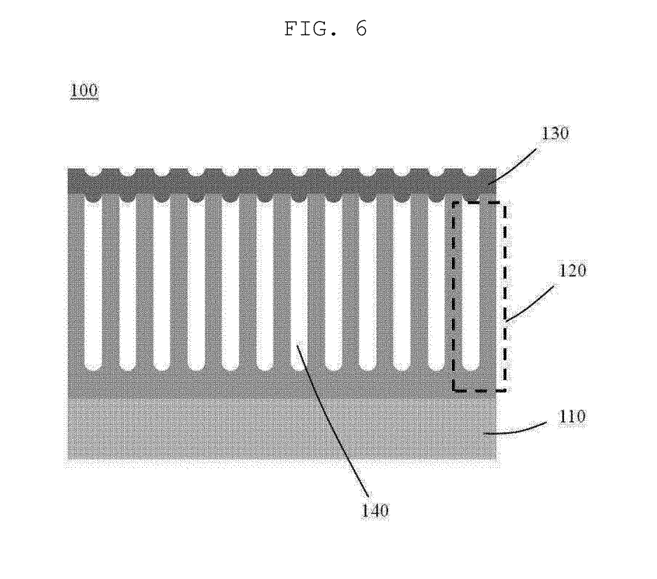

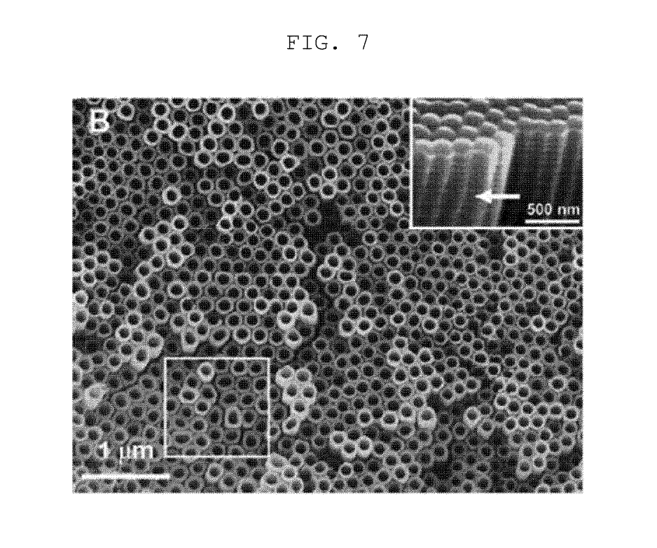

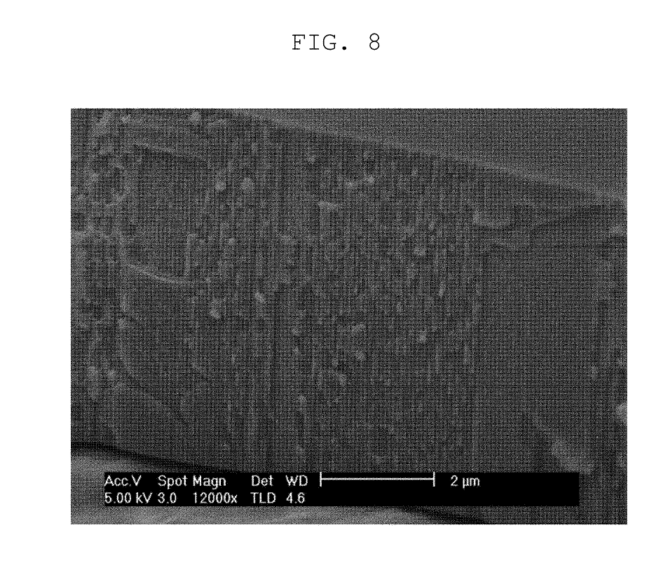

Afterwards, the wet coating step is a step of forming a coating film 130 by coating the top portions of the number of grown nanotubes 120 with a liquid composite by wet coating. In the wet coating step, the viscosity of the liquid composite is controlled in the range from 1 cP to 1000 cP. As illustrated in FIG. 5, when the coating film 130 is formed by coating the number of nanotubes 120 with the liquid composite, the viscosity of which is in the above-described range, the coating film 130 is deformed in the direction of arrows, due to the capillary effect induced by the number of nanotubes 120. This consequently forms corrugations on the surface of the coating film 130, as illustrated in FIG. 6. The corrugations function as a structure for disturbing a waveguide mode to minimize the loss of light emitted by the OLED. When the viscosity of the liquid composite for forming the coating film 130 is less than 1 cP, the formation of the coating film 130 is difficult, since the liquid composite flows into the hollow inner spaces of the nanotubes 120. When the viscosity of the liquid composite exceeds 1000 cP, the corrugations are not formed on the surface of the coating film 130, since the deformation of the coating film 130 due to the capillary effect is not enabled. In addition, when the top ends of the number of nanotubes 120 are closed by the coating film 130 due to the wet coating step, the number of air gaps 140 for scattering light emitted by the OLED are formed in the number of nanotubes 120 along the longitudinal direction of the nanotubes 120.

When the wet coating step of forming the coating film 130 on the number of nanotubes 120 is finished, the light extraction substrate 100 for an OLED device according to an exemplary embodiment is manufactured.

As set forth above, the method of manufacturing the light extraction substrate for an OLED device according to the exemplary embodiment manufactures the light extraction substrate 100 having the corrugated structure using a simple process consisting of the anodic oxidation step and the wet coating step. The method of manufacturing the light extraction substrate for an OLED device according to the exemplary embodiment can improve processing efficiency and significantly reduce manufacturing costs and manufacturing times compared to conventional pattering or photolithography due to more simplified processing, thereby improving productivity in the manufacturing of light extraction substrates compared to conventional cases.

The foregoing descriptions of specific exemplary embodiments of the present disclosure have been presented with respect to the drawings. They are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

1. A light extraction substrate for an organic light-emitting device, comprising:
a base substrate;
a number of nanotubes disposed on the base substrate; and
a coating film disposed on the number of nanotubes to close top ends of the number of nanotubes to form a number of air gaps in the number of nanotubes, respectively, the coating film having corrugations formed on a surface thereof due to a capillary effect inducted by the number of nanotubes.

2. The light extraction substrate of claim 1, wherein surface portions of the coating film located above the number of air gaps form downwardly convex surface portions.

3. The light extraction substrate of claim 1, wherein an aspect ratio of the number of air gaps is smaller than 1.

4. The light extraction substrate of claim 1, wherein the coating film is formed from a material having a refractive index different from a refractive index of a material from which the number of nanotubes are formed.

5. The light extraction substrate of claim 1, wherein the number of nanotubes are formed from a metal oxide.

6. The light extraction substrate of claim 5, wherein the number of nanotubes are formed from a titanium oxide.

7. The light extraction substrate of claim 1, further comprising filler disposed in at least portions of the number of air gaps, the filler being formed from a material having a refractive index different from a refractive index of a material from which the number of nanotubes are formed.

8. The light extraction substrate of claim 7, further comprising one or more scattering particles dispersed in the filler.

9. The light extraction substrate of claim 8, wherein the scattering particles respectively comprise a core and a shell surrounding the core, the shell being formed from a material having a refractive index different from a refractive index of the core.

10. The light extraction substrate of claim 9, wherein the core comprises a hollow portion.

11. The light extraction substrate of claim 1, wherein the base substrate comprises a flexible substrate.

12. The light extraction substrate of claim 11, wherein the base substrate comprises a thin glass sheet having a thickness of 1.5 mm or less.

13. An organic light-emitting device comprising the light extraction substrate as claimed claim 1 in a portion through which generated light exits.

14. A method of manufacturing a light extraction substrate for an organic light-emitting device, the method comprising:
growing a number of nanotubes on a surface of a metal base material by performing anodic oxidation on a surface of the metal base material; and
forming a coating film by coating the number of nanotubes with a liquid composite by wet coating,
wherein corrugations are formed on a surface of the coating film by a capillary effect induced by the number of nanotubes in the wet coating.

15. The method of claim 14, wherein a viscosity of the liquid composite is controlled in a range from 1 cP to 1000 cP in the wet coating.

16. The method of claim 14, wherein the metal base material used in the anodic oxidation is formed from titanium or a titanium alloy.

17. The method of claim 14, wherein top ends of the number of nanotubes are closed by the coating film, thereby forming a number of air gaps within the number of nanotubes, respectively, in a longitudinal direction of the number of nanotubes.

18. The method of claim 14, further comprising disposing filler within the number of nanotubes before the wet coating, the filler being formed from a material having a refractive index different from a refractive index of the number of nanotubes.

19. The method of claim 18, wherein scattering particles are dispersed in the filler in the process of disposing the filler.
